(19) United States
(12) Patent Application Publication
(10) Pub. No.: US 2024/0207896 A1
(43) Pub. Date: Jun. 27, 2024

(54) HAPTIC SUBSTRATE AND ELECTRONIC APPARATUS

(71) Applicants: Beijing BOE Technology Development Co., Ltd., Beijing (CN); BOE Technology Group Co., Ltd., Beijing (CN)

(72) Inventors: Yuju Chen, Beijing (CN); Hui Hua, Beijing (CN); Xiaotong Liu, Beijing (CN)

(73) Assignees: Beijing BOE Technology Development Co., Ltd., Beijing (CN); BOE Technology Group Co., Ltd., Beijing (CN)

(21) Appl. No.: 17/905,816

(22) PCT Filed: Dec. 27, 2021
(86) PCT No.: PCT/CN2021/141545

§ 371 Date: Jul. 6, 2023

(51) Int. Cl. B06B 1/06; G06F 3/01; H10N 39/00

(52) U.S. Cl. CPC B06B 1/0692; G06F 3/016; H10N 39/00

(57) ABSTRACT

A haptic substrate is provided. The haptic substrate includes a first electrode layer; an electroactive layer on the first electrode layer; a second electrode layer on a side of the electroactive layer away from the first electrode layer; a first pad layer electrically connected to the first electrode layer; and a second pad layer on a side of the second electrode layer away from the electroactive layer, the second pad layer being connected to the second electrode layer. In a region where an orthographic projection of the second electrode layer on a base substrate overlaps with the orthographic projection of the second pad layer on the base substrate, at least 30% of the second pad layer is in direct contact with the second electrode layer.

### TECHNICAL FIELD

The present invention relates to haptic technology, more particularly, to a haptic substrate and an electronic apparatus.

### BACKGROUND

Haptic technology enables device-human interaction. Haptic technology may be classified into two categories, including vibration feedback, and haptic reproduction. Haptic reproduction technology enables perception of characteristics of an object through a touch, achieving highly efficient and natural interaction in a multi-media environment.

### SUMMARY

In one aspect, the present disclosure provides a haptic substrate, comprising a first electrode layer; an electroactive layer on the first electrode layer; a second electrode layer on a side of the electroactive layer away from the first electrode layer; a first pad layer electrically connected to the first electrode layer; and a second pad layer on a side of the second electrode layer away from the electroactive layer, the second pad layer being connected to the second electrode layer; wherein in a region where an orthographic projection of the second electrode layer on a base substrate overlaps with the orthographic projection of the second pad layer on the base substrate, at least 30% of the second pad layer is in direct contact with the second electrode layer.

Optionally, in the region where the orthographic projection of the second electrode layer on the base substrate overlaps with the orthographic projection of the second pad layer on the base substrate, an entirety of the second pad layer is in direct contact with the second electrode layer.

Optionally, at least 30% of the region where the orthographic projection of the second electrode layer on the base substrate overlaps with the orthographic projection of the second pad layer on the base substrate is absent of an insulating layer between the second electrode layer and the second pad layer.

Optionally, an entirety of the region where the orthographic projection of the second electrode layer on the base substrate overlaps with the orthographic projection of the second pad layer on the base substrate is absent of an insulating layer between the second electrode layer and the second pad layer.

Optionally, the haptic substrate comprises one or more units arranged along a first direction configured to perform tactile reproduction upon actuation; wherein the electroactive layer comprises a plurality of electroactive blocks; the second electrode layer comprises a plurality of second electrode blocks; the second pad layer comprises a plurality of second pads; and a respective unit of the one or more units comprises a respective electroactive block of the plurality of electroactive blocks, the plurality of second electrode blocks, and a respective second pad of the plurality of second pads.

Optionally, the plurality of second electrode blocks in the respective unit are configured to form a first electric field with the first electrode layer; the plurality of second pads in the respective unit are configured to transmit a signal to the second electrode layer to form a second electric field with the first electrode layer; and the first electric field and the second electric field are in phase with respect to each other.

Optionally, the respective second pad comprises a plurality of ring structures and a plurality of bridges alternately arranged along a second direction.

Optionally, the respective unit comprises a plurality of subunits arranged along the second direction; and a respective subunit comprises a respective second electrode block of the plurality of second electrode blocks, and a respective ring structure of the plurality of ring structures, adjacent ring structures of the plurality of ring structures being connected to each other through a respective bridge of the plurality of bridges.

Optionally, an orthographic projection of the respective second electrode block on the base substrate completely covers an orthographic projection of an inner periphery of the respective ring structure on the base substrate; and an orthographic projection of an outer periphery of the respective ring structure on the base substrate is at least partially overlapping with the orthographic projection of the respective second electrode block on the base substrate.

Optionally, an entirety of the respective ring structure is in direct contact with the respective second electrode block.

Optionally, the respective electroactive block is a unitary structure, the respective second pad is a unitary structure, and the plurality of second electrode blocks are spaced apart from each other.

Optionally, an orthographic projection of the respective second pad on the base substrate at least partially overlaps with an orthographic projection of each of the plurality of second electrode blocks on the base substrate; and the orthographic projection of the plurality of second electrode blocks on the base substrate covers at least 50% of the orthographic projection of the respective second pad on the base substrate.

Optionally, an orthographic projection of the respective electroactive block on the base substrate covers at least 50% of an orthographic projection of the plurality of second electrode blocks on the base substrate; and the orthographic projection of the respective electroactive block on the base substrate covers at least 50% of an orthographic projection of the respective second pad on the base substrate.

Optionally, an orthographic projection of the respective electroactive block on the base substrate completely covers an orthographic projection of the plurality of second electrode blocks on the base substrate, and completely covers an orthographic projection of the respective second pad on the base substrate.

Optionally, the respective second pad is in direct contact with each of the plurality of second electrode blocks; and the respective electroactive block is in direct contact with each of the plurality of second electrode blocks.

Optionally, the electroactive layer is a unitary electroactive layer spans over the one or more units.

Optionally, the haptic substrate comprises two units configured to perform tactile reproduction upon actuation, the two units being on two sides of the haptic substrate, respectively.

Optionally, the haptic substrate further comprises a planarization layer between the electroactive layer and the second electrode layer.

Optionally, the haptic substrate is absent of any via through which the second pad layer is connected to the second electrode layer.

In another aspect, the present disclosure provides an electronic apparatus, comprising the haptic substrate described herein, and a driving circuit connected to the haptic substrate

### BRIEF DESCRIPTION OF THE FIGURES

The following drawings are merely examples for illustrative purposes according to various disclosed embodiments and are not intended to limit the scope of the present invention.

FIG. 1A is a schematic diagram illustrating the structure of a haptic substrate in some embodiments according to the present disclosure.

FIG. 1B is a schematic diagram illustrating the structure of a haptic substrate in some embodiments according to the present disclosure.

FIG. 2A is a plan view of a haptic substrate in some embodiments according to the present disclosure.

FIG. 2B is a schematic diagram illustrating the structure of a first electrode layer in a haptic substrate depicted in FIG. 2A.

FIG. 2C is a schematic diagram illustrating the structure of an electroactive layer in a haptic substrate depicted in FIG. 2A.

FIG. 2D is a schematic diagram illustrating the structure of a second electrode layer in a haptic substrate depicted in FIG. 2A.

FIG. 2E is a schematic diagram illustrating the structure of a first pad layer and a second pad layer in a haptic substrate depicted in FIG. 2A.

FIG. 3 is a cross-sectional view along an A-A′ line in FIG. 2A.

FIG. 4 illustrates a vibration pattern produced on a touch surface of a haptic substrate depicted in FIG. 2A.

FIG. 5A is a plan view of a haptic substrate in some embodiments according to the present disclosure.

FIG. 5B is a schematic diagram illustrating the structure of a first electrode layer in a haptic substrate depicted in FIG. 5A.

FIG. 5C is a schematic diagram illustrating the structure of an electroactive layer in a haptic substrate depicted in FIG. 5A.

FIG. 5D is a schematic diagram illustrating the structure of a planarization layer in a haptic substrate depicted in FIG. 5A.

FIG. 5E is a schematic diagram illustrating the structure of a second electrode layer in a haptic substrate depicted in FIG. 5A.

FIG. 5F is a schematic diagram illustrating the structure of a first pad layer and a second pad layer in a haptic substrate depicted in FIG. 5A.

FIG. 6 is a cross-sectional view along a B-B′ line in FIG. 5A.

FIG. 7A is a plan view of a haptic substrate in some embodiments according to the present disclosure.

FIG. 7B is a schematic diagram illustrating the structure of a first electrode layer in a haptic substrate depicted in FIG. 7A.

FIG. 7C is a schematic diagram illustrating the structure of an electroactive layer in a haptic substrate depicted in FIG. 7A.

FIG. 7D is a schematic diagram illustrating the structure of a second electrode layer in a haptic substrate depicted in FIG. 7A.

FIG. 7E is a schematic diagram illustrating the structure of a first pad layer and a second pad layer in a haptic substrate depicted in FIG. 7A.

FIG. 8A is a plan view of a haptic substrate in some embodiments according to the present disclosure.

FIG. 8B is a schematic diagram illustrating the structure of a first electrode layer in a haptic substrate depicted in FIG. 8A.

FIG. 8C is a schematic diagram illustrating the structure of an electroactive layer in a haptic substrate depicted in FIG. 8A.

FIG. 8D is a schematic diagram illustrating the structure of a second electrode layer in a haptic substrate depicted in FIG. 8A.

FIG. 8E is a schematic diagram illustrating the structure of a first pad layer and a second pad layer in a haptic substrate depicted in FIG. 8A.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a haptic substrate and a haptic reproduction apparatus that substantially obviate one or more of the problems due to limitations and disadvantages of the related art. In one aspect, the present disclosure provides a haptic substrate. In some embodiments, the haptic substrate includes a first electrode layer; an electroactive layer on the first electrode layer; a second electrode layer on a side of the electroactive layer away from the first electrode layer; a first pad layer electrically connected to the first electrode layer; and a second pad layer on a side of the second electrode layer away from the electroactive layer, the second pad layer being connected to the second electrode layer. Optionally, in a region where the orthographic projection of the second electrode layer on a base substrate overlaps with the orthographic projection of the second pad layer on the base substrate, at least 30% of the second pad layer is in direct contact with the second electrode layer.

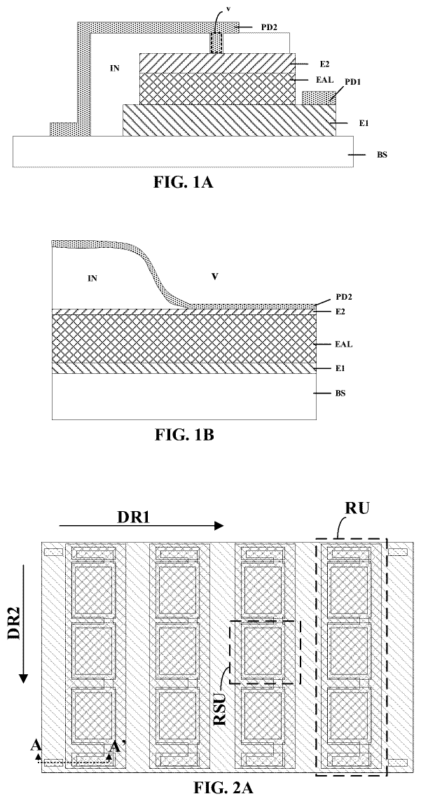

FIG. 1A is a schematic diagram illustrating the structure of a haptic substrate in some embodiments according to the present disclosure. Referring to FIG. 1A, the haptic substrate in some embodiments includes a base substrate BS, a first electrode layer E1 on the base substrate BS, an electroactive layer EAL on a side of the first electrode layer E1 away from the base substrate BS, a second electrode layer E2 on a side of the electroactive layer EAL away from the first electrode layer E1, an insulating layer IN on a side of the second electrode layer E2 away from the electroactive layer EAL, a second pad layer PD2 on a side of the insulating layer IN away from the second electrode layer E2, and a first pad layer PD1 on a side of the first electrode layer E1 away from the base substrate BS. The first pad layer PD1 is in direct contact with the first electrode layer E1. The second pad layer PD2 is connected to the second electrode layer E2 through a via v extending through the insulating layer IN.

FIG. 1B is a schematic diagram illustrating the structure of a haptic substrate in some embodiments according to the present disclosure. Referring to FIG. 1B, the second pad layer PD2 extends into the via v to connect to the second electrode layer E2. The insulating layer IN has a side wall along the via v, and the side wall has a slope.

As used herein the term “electroactive material” refers to a material that reversibly changes one or more characteristic body dimension by an amount depending on an applied electrical voltage. As used herein, the term “electroactive layer” refers to a layer in the present substrate that includes an electroactive material, and is capable of reversibly changing one or more characteristic body dimension by an amount depending on an applied electrical voltage. Optionally, the electroactive material is an electrostrictive material. Stress and strain response of the electrostrictive material to an electric field is proportional to the square of the electric field. Optionally, the electroactive material is a piezoelectric material. Stress and strain response of the piezoelectric material to an electric field is proportional to the electric field.

Any appropriate electrostrictive material may be used for making the electroactive layer, e.g., electrostrictive ceramics, electrostrictive polymers, electrostrictive valves, etc. Examples of appropriate electrostrictive materials include, but are not limited to, a polyurethane containing material (e.g., a doped polyurethane material), polyvinylidene fluoride, lead magnesium niobate, lead magnesium niobate-lead titanate, lanthanum doped lead zirconate titanate, barium doped lead zirconate titanate, and various substitutes and derivatives thereof (e.g., doped with one or more dopant).

Any appropriate piezoelectric material may be used for making the electroactive layer. Examples of appropriate piezoelectric materials include, but are not limited to, lead zirconium titanate, berlinite, zinc oxide, barium titanate, lead titanate, and various substitutes and derivatives thereof (e.g., doped with one or more dopant).

When a voltage signal (e.g., an alternating current signal) is applied to the haptic substrate (e.g., through the first electrode layer E1 and the second electrode layer E2), structural vibration is formed on a surface of the haptic substrate, particularly when the alternating current signal having a resonant frequency is provided. When a finger is placed on the surface of the haptic substrate, surface tactile friction control can be achieved. The amplitude of the vibration is positively correlated to the amplitude of the voltage signal provided. The inventors of the present disclosure discover that the vibration force may result in peeling of one or more layers in the haptic substrate, particularly where the adhesion between adjacent layers are relatively weak.

Referring to FIG. 1A and FIG. 1B, the second pad layer PD2 in a region inside the via v is in contact with a surface of the insulating layer IN having a slope. Because the contact in this region is non-horizontal, stress distribution upon the vibration in the slope region tends to be more non-uniform. Moreover, the second pad layer PD2 typically has a relatively small thickness (e.g., less than 200 nm in one example). Due to the highly non-uniform stress distribution in this slope region, the second pad layer PD2 is subject to distortion, leading to deformation in one or more portions of the second pad layer PD2. For example, the thickness of one or more portions of the second pad layer PD2 may be reduced when the haptic substrate is subject to vibration for an elongated period. A reduced thickness renders the second pad layer PD2 more prone to damage such as electrical breakdown. The inventors of the present disclosure discover that frequently the damage occurs inside the via where the second pad layer PD2 extends through the slope.

The inventors of the present disclosure discover a unique substrate structure that obviate the above issues. The intricate structure of the present substrate dramatically enhances the reliability and voltage tolerance of the haptic substrate, effectively eliminates the electrical breakdown issues, and maintains sufficient energy input area and vibration output.

In some embodiments, the haptic substrate according to the present disclosure lacks an insulating layer between the second electrode layer E2 and the second pad layer PD2.

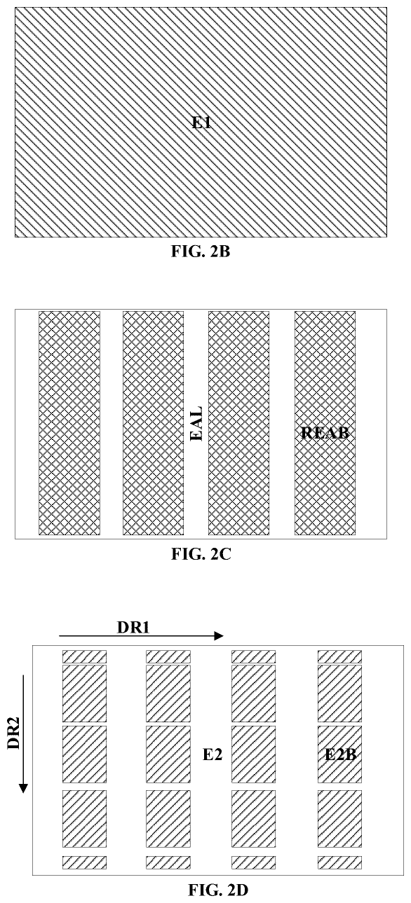

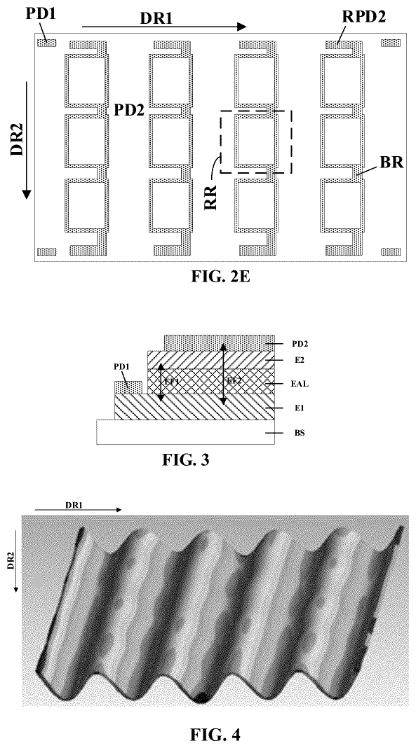

FIG. 2A is a plan view of a haptic substrate in some embodiments according to the present disclosure. FIG. 2B is a schematic diagram illustrating the structure of a first electrode layer in a haptic substrate depicted in FIG. 2A. FIG. 2C is a schematic diagram illustrating the structure of an electroactive layer in a haptic substrate depicted in FIG. 2A. FIG. 2D is a schematic diagram illustrating the structure of a second electrode layer in a haptic substrate depicted in FIG. 2A. FIG. 2E is a schematic diagram illustrating the structure of a first pad layer and a second pad layer in a haptic substrate depicted in FIG. 2A. FIG. 3 is a cross-sectional view along an A-A′ line in FIG. 2A. Referring to FIG. 2A to FIG. 2E, and FIG. 3, the haptic substrate in some embodiments includes a base substrate BS, a first electrode layer E1 on the base substrate BS, an electroactive layer EAL on a side of the first electrode layer E1 away from the base substrate BS, a second electrode layer E2 on a side of the electroactive layer EAL away from the first electrode layer E1, a second pad layer PD2 on a side of the second electrode layer E2 away from the electroactive layer EAL, and a first pad layer PD1 on a side of the first electrode layer E1 away from the base substrate BS. The first pad layer PD1 is in direct contact with the first electrode layer E1.

Optionally, the first pad layer PD1 and the second pad layer PD2 are in a same layer. As used herein, the term “same layer” refers to the relationship between the layers simultaneously formed in the same step. In one example, the first pad layer PD1 and the second pad layer PD2 are in a same layer when they are formed as a result of one or more steps of a same patterning process performed in a material deposited in a same deposition process. In another example, the first pad layer PD1 and the second pad layer PD2 can be formed in a same layer by simultaneously performing the step of forming the first pad layer PD1 and the step of forming the second pad layer PD2. The term “same layer” does not always mean that the thickness of the layer or the height of the layer in a cross-sectional view is the same.

In some embodiments, an insulating layer between the second electrode layer E2 and the second pad layer PD2 is absent. Referring to FIG. 3, in a region where an orthographic projection of the second electrode layer E2 on a base substrate BS overlaps with an orthographic projection of the second pad layer PD2 on the base substrate BS, the second pad layer PD2 is in direct contact with the second electrode layer E2. It is not necessary for the second pad layer PD2 to extend through a via to connect to the second electrode layer E2. By having this unique structure, the second pad layer PD2 is disposed on a substantially horizontal plane, stress distribution throughout an entirety of the second pad layer PD2 is substantially uniform, obviating the electrical breakdown issue.

In some embodiments, in the region where the orthographic projection of the second electrode layer E2 on the base substrate BS overlaps with the orthographic projection of the second pad layer PD2 on the base substrate BS, at least 30% (e.g., at least 35%, at least 40%, at least 45%, at least 50%, at least 55%, at least 60%, at least 65%, at least 70%, at least 75%, at least 80%, at least 85%, at least 90%, at least 95%, at least 99%, or 100%) of the second pad layer PD2 is in direct contact with the second electrode layer E2. Optionally, in the region where the orthographic projection of the second electrode layer E2 on the base substrate BS overlaps with the orthographic projection of the second pad layer PD2 on the base substrate BS, an entirety of the second pad layer PD2 is in direct contact with the second electrode layer E2.

In some embodiments, at least 30% (e.g., at least 35%, at least 40%, at least 45%, at least 50%, at least 55%, at least 60%, at least 65%, at least 70%, at least 75%, at least 80%, at least 85%, at least 90%, at least 95%, at least 99%, or 100%) of the region where the orthographic projection of the second electrode layer E2 on the base substrate BS overlaps with the orthographic projection of the second pad layer PD2 on the base substrate BS is absent of an insulating layer between the second electrode layer E2 and the second pad layer PD2. Optionally, an entirety of the region where the orthographic projection of the second electrode layer E2 on the base substrate BS overlaps with the orthographic projection of the second pad layer PD2 on the base substrate BS is absent of an insulating layer between the second electrode layer E2 and the second pad layer PD2.

In some embodiments, the haptic substrate includes one or more vibration units. Optionally, the haptic substrate includes a plurality of units arranged along a first direction DR1. In some embodiments, the plurality of units are a plurality of tactile reproduction units configured to perform tactile reproduction upon actuation. A respective unit RU is denoted in FIG. 2A. FIG. 4 illustrates a vibration pattern produced on a touch surface of a haptic substrate depicted in FIG. 2A. Referring to FIG. 4, when the plurality of tactile reproduction units are actuated, each of the plurality of tactile reproduction units is configured to deform the touch surface of the haptic substrate longitudinally, e.g., the deformation along the second direction DR2. The vibration curve may be understood as having a plurality of node points, each node point in the vibration curve remains relatively stationary, while positions between adjacent node points vibrate up and down thereby forming peaks and valleys.

In some embodiments, an alternating current signal is provided to the second pad layer PD2, the alternating current signal is transmitted to the second electrode layer E2. In the present substrate, the second electrode layer E2 is configured to form a first electric field (denoted as EF1 in FIG. 3) with the first electrode layer E1 (which may be provided with a ground voltage), and the second pad layer PD2 is configured to transmit a signal to the second electrode layer to form a second electric field (denoted as EF2 in FIG. 3) with the first electrode layer E1. The first electric field and the second electric field have a same phase. The unique structure of the present substrate has an enhanced energy input area to maintain vibration characteristics.

In some embodiments, the electroactive layer EAL includes a plurality of electroactive blocks; the second electrode layer E2 includes a plurality of second electrode blocks E2B, and the second pad layer PD2 includes a plurality of second pads. In some embodiments, a respective unit RU includes a respective electroactive block REAB of the plurality of electroactive blocks, the plurality of second electrode blocks E2B, and a respective second pad RPD2 of the plurality of second pads. The plurality of second electrode blocks E2B are arranged along the second direction DR2. The respective second pad RPD2 spans over the plurality of second electrode blocks E2B, and is in direct contact with the plurality of second electrode blocks E2B. Optionally, the respective second pad RPD2 is in direct contact with each of the plurality of second electrode blocks E2B.

In some embodiments, an orthographic projection of the respective second pad RPD2 on the base substrate BS at least partially overlaps with an orthographic projection of the plurality of second electrode blocks E2B on the base substrate BS. Optionally, the orthographic projection of the respective second pad RPD2 on the base substrate BS at least partially overlaps with an orthographic projection of each of the plurality of second electrode blocks E2B on the base substrate BS. Optionally, the orthographic projection of the plurality of second electrode blocks E2B on the base substrate BS covers at least 50% (e.g., at least 55%, at least 60%, at least 65%, at least 70%, at least 75%, at least 80%, at least 85%, at least 90%, or at least 95%) of the orthographic projection of the respective second pad RPD2 on the base substrate BS.

In some embodiments, the respective electroactive block REAB is in direct contact with the plurality of second electrode blocks E2B. An orthographic projection of the respective electroactive block REAB on the base substrate BS at least partially overlaps with an orthographic projection of the plurality of second electrode blocks E2B on the base substrate BS. Optionally, the orthographic projection of the respective electroactive block REAB on the base substrate BS at least partially overlaps with an orthographic projection of each of the plurality of second electrode blocks E2B on the base substrate BS. Optionally, the orthographic projection of the respective electroactive block REAB on the base substrate BS covers at least 50% (e.g., at least 55%, at least 60%, at least 65%, at least 70%, at least 75%, at least 80%, at least 85%, at least 90%, at least 95%, or at least 99%) the orthographic projection of the plurality of second electrode blocks E2B on the base substrate BS. Optionally, the orthographic projection of the respective electroactive block REAB on the base substrate BS completely covers the orthographic projection of the plurality of second electrode blocks E2B on the base substrate BS.

In some embodiments, an orthographic projection of the respective electroactive block REAB on the base substrate BS at least partially overlaps with an orthographic projection of the respective second pad RPD2 on the base substrate BS. Optionally, the orthographic projection of the respective electroactive block REAB on the base substrate BS covers at least 50% (e.g., at least 55%, at least 60%, at least 65%, at least 70%, at least 75%, at least 80%, at least 85%, at least 90%, at least 95%, or at least 99%) the orthographic projection of the respective second pad RPD2 on the base substrate BS. Optionally, the orthographic projection of the respective electroactive block REAB on the base substrate BS completely covers the orthographic projection of the respective second pad RPD2 on the base substrate BS.

In some embodiments, the respective electroactive block REAB is a unitary structure, the respective second pad RPD2 is a unitary structure, whereas the plurality of second electrode blocks E2B are spaced apart from each other.

In some embodiments, the respective unit RU includes a plurality of subunits arranged along the second direction DR2. A respective subunit RSU is denoted in FIG. 2A. In some embodiments, the respective subunit RSU includes a respective second electrode block of the plurality of second electrode blocks E2B, and a respective ring structure RR of the respective second pad RPD2. The respective second pad RPD2 includes a plurality of ring structures and a plurality of bridges alternately arranged along the second direction DR2. Adjacent ring structures of the plurality of ring structures are connected to each other through a respective bridge BR.

As used herein, the term “ring” or “ring structure” refers to a structure or portion of a structure having a hole there through. A ring structure may be formed of a square, rectangle, triangle or another shape with a hole there through, or may be essentially round like a doughnut. In some embodiments, the ring structure is formed of a square or rectangle shape with a hole there through. Optionally, the ring is a square ring. Optionally, the ring is a rectangle ring. As used herein, a ring structure does not require that the ring shape be unbroken, and the term is intended to encompass structures that are substantially closed, but that comprise a break or a gap in the ring shape. Optionally, the ring structure is an unbroken ring.

In some embodiments, an orthographic projection of the respective ring structure RR on the base substrate BS is at least partially overlapping with an orthographic projection of the respective second electrode block on the base substrate BS, and an orthographic projection of the respective bridge BR on the base substrate BS is at least partially non-overlapping with the orthographic projection of the respective second electrode block on the base substrate BS. The respective ring structure RR has an inner periphery and an outer periphery. Optionally, an orthographic projection of the inner periphery of the respective ring structure RR on the base substrate BS is at least partially overlapping with the orthographic projection of the respective second electrode block on the base substrate BS. Optionally, the orthographic projection of the respective second electrode block on the base substrate BS completely covers the orthographic projection of the inner periphery of the respective ring structure RR on the base substrate BS. Optionally, an orthographic projection of the outer periphery of the respective ring structure RR on the base substrate BS is at least partially overlapping with the orthographic projection of the respective second electrode block on the base substrate BS.

Optionally, the first electrode layer E1 has a thickness in a range of 100 nm to 500 nm, e.g., 100 nm to 200 nm, 200 nm to 300 nm, 300 nm to 400 nm, or 400 nm to 500 nm.

Optionally, the electroactive layer EAL has a thickness in a range of 0.5 μm to 5.0 μm, e.g., 0.5 μm to 1.0 μm, 1.0 μm to 1.5 μm, 1.5 μm to 2.0 μm, 2.0 μm to 2.5 μm, 2.5 μm to 3.0 μm, 3.0 μm to 3.5 μm, 3.5 μm to 4.0 μm, 4.0 μm to 4.5 μm, or 4.5 μm to 5.0 μm.

Optionally, the second electrode layer E2 has a thickness in a range of 100 nm to 500 nm, e.g., 100 nm to 200 nm, 200 nm to 300 nm, 300 nm to 400 nm, or 400 nm to 500 nm.

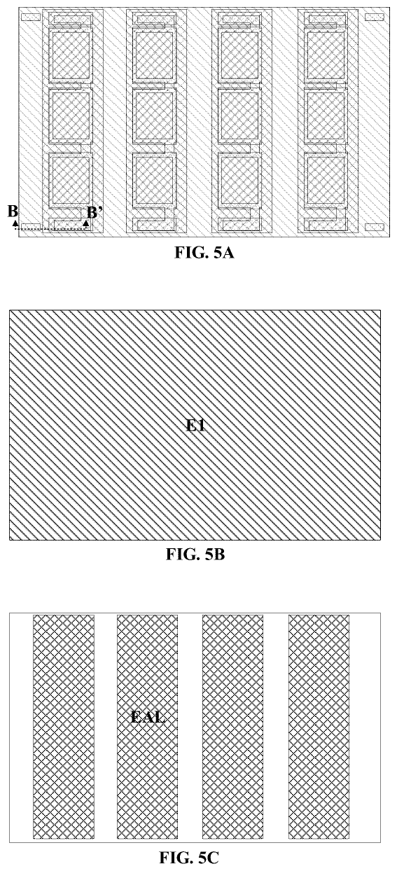

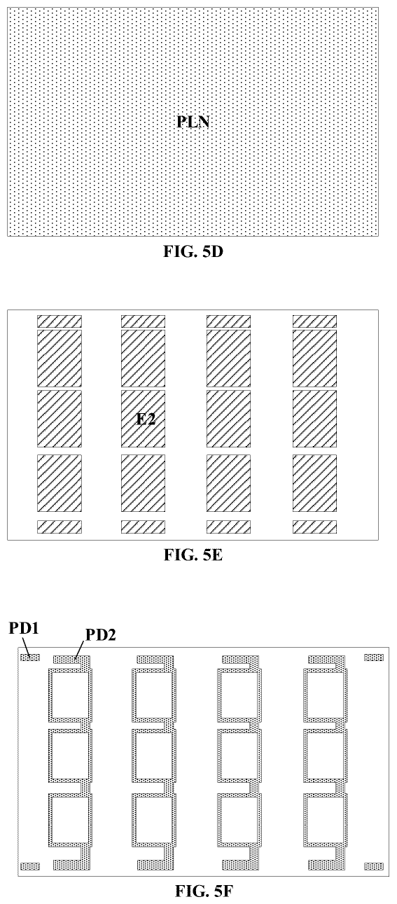

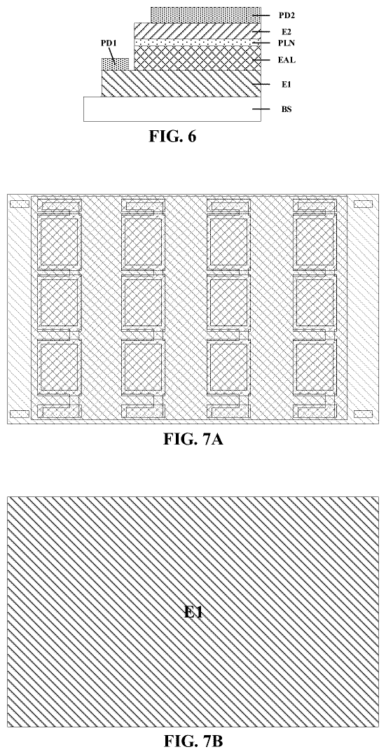

FIG. 5A is a plan view of a haptic substrate in some embodiments according to the present disclosure. FIG. 5B is a schematic diagram illustrating the structure of a first electrode layer in a haptic substrate depicted in FIG. 5A. FIG. 5C is a schematic diagram illustrating the structure of an electroactive layer in a haptic substrate depicted in FIG. 5A. FIG. 5D is a schematic diagram illustrating the structure of a planarization layer in a haptic substrate depicted in FIG. 5A. FIG. 5E is a schematic diagram illustrating the structure of a second electrode layer in a haptic substrate depicted in FIG. 5A. FIG. 5F is a schematic diagram illustrating the structure of a first pad layer and a second pad layer in a haptic substrate depicted in FIG. 5A. FIG. 6 is a cross-sectional view along a B-B′ line in FIG. 5A. Referring to FIG. 5A to FIG. 5F, and FIG. 6, the haptic substrate in some embodiments further includes a planarization layer PLN between the electroactive layer EAL and the second electrode layer E2. The planarization layer PLN is configured to planarize the surface of the electroactive layer EAL, e.g., repairing cracks in the electroactive layer EAL, if any. The planarization layer PLN may be made of an organic or inorganic insulating material such as polyimide and silicon oxide. In one example, the planarization layer PLN has a thickness less than 100 nm.

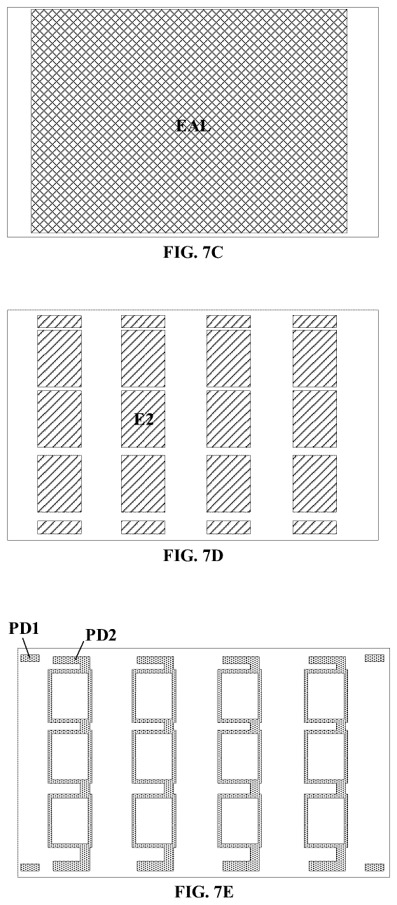

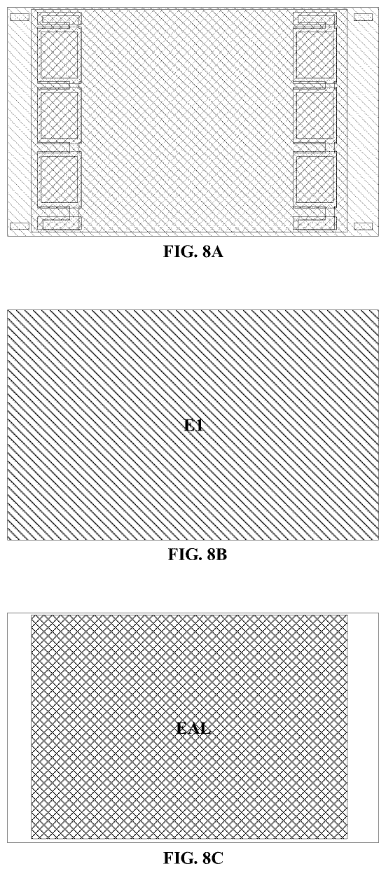

FIG. 7A is a plan view of a haptic substrate in some embodiments according to the present disclosure. FIG. 7B is a schematic diagram illustrating the structure of a first electrode layer in a haptic substrate depicted in FIG. 7A. FIG. 7C is a schematic diagram illustrating the structure of an electroactive layer in a haptic substrate depicted in FIG. 7A. FIG. 7D is a schematic diagram illustrating the structure of a second electrode layer in a haptic substrate depicted in FIG. 7A. FIG. 7E is a schematic diagram illustrating the structure of a first pad layer and a second pad layer in a haptic substrate depicted in FIG. 7A. Referring to FIG. 7A to FIG. 7E, the haptic substrate in some embodiments includes a unitary electroactive layer. The electroactive layer EAL spans over the plurality of units (e.g., the plurality of tactile reproduction units configured to perform tactile reproduction upon actuation).

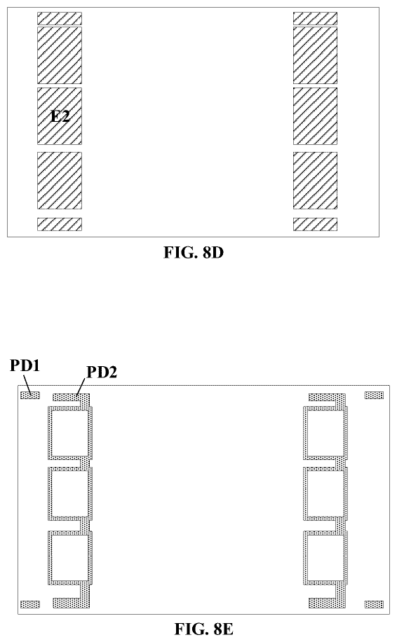

FIG. 8A is a plan view of a haptic substrate in some embodiments according to the present disclosure. FIG. 8B is a schematic diagram illustrating the structure of a first electrode layer in a haptic substrate depicted in FIG. 8A. FIG. 8C is a schematic diagram illustrating the structure of an electroactive layer in a haptic substrate depicted in FIG. 8A. FIG. 8D is a schematic diagram illustrating the structure of a second electrode layer in a haptic substrate depicted in FIG. 8A. FIG. 8E is a schematic diagram illustrating the structure of a first pad layer and a second pad layer in a haptic substrate depicted in FIG. 8A. Referring to FIG. 8A to FIG. 8E, the haptic substrate in some embodiments include two units, e.g., two tactile reproduction units configured to perform tactile reproduction upon actuation. The two units are respectively disposed on two sides of the haptic substrate.

In another aspect, the present disclosure further provides an electronic apparatus having the haptic substrate described herein or fabricated by a method described herein. In some embodiments, the electronic apparatus further includes a driving circuit connected to the haptic substrate. Optionally, the driving circuit is configured to provide driving signals to the first electrode layer and the second electrode layer. In one example, the driving circuit is configured to provide a ground voltage to the first electrode layer. In another example, the driving circuit is configured to provide an alternating current signal to the second electrode layer. In some embodiments, the electronic apparatus further includes a display panel. In some embodiments, the electronic apparatus further includes a touch electrode layer configured to detect a touch on a surface of the electronic apparatus.

In another aspect, the present disclosure further provides a method of driving a haptic apparatus. In some embodiments, the method includes provide driving signals to a first electrode layer and a second electrode layer of a haptic substrate, wherein the haptic substrate including the first electrode layer; an electroactive layer on the first electrode layer; the second electrode layer on a side of the electroactive layer away from the first electrode layer; a first pad layer electrically connected to the first electrode layer; and a second pad layer on a side of the second electrode layer away from the electroactive layer, the second pad layer being connected to the second electrode layer. Optionally, in a region where the orthographic projection of the second electrode layer on a base substrate overlaps with the orthographic projection of the second pad layer on the base substrate, at least 30% of the second pad layer is in direct contact with the second electrode layer.

In some embodiments, the method includes providing a ground voltage to the first electrode layer, and providing an alternating current signal to the second electrode layer.

In some embodiments, the method further includes obtaining a touch signal upon a touch on a surface of an electronic apparatus having the haptic substrate and a touch electrode layer; and deriving touch information such as touch position of the touch from the touch signal. Optionally, the method further includes providing the driving signals to a first electrode layer and a second electrode layer based on the touch information derived from the touch signal.

In some embodiments, the method further includes determining a vibration position and/or a vibration mode based on the touch information; and determining the driving signals required to enable the vibration position and/or the vibration mode.

In some embodiments, the step of determining the driving signals required to enable the vibration position and/or the vibration mode includes determining one or more of frequency and amplitude of an alternating current signal; and transmitting the alternating current signal to the second electrode layer.

In another aspect, the present disclosure further provides a method of fabricating a haptic substrate. In some embodiments, the method includes forming a first electrode layer; forming an electroactive layer on the first electrode layer; forming a second electrode layer on a side of the electroactive layer away from the first electrode layer; forming a first pad layer electrically connected to the first electrode layer; and forming a second pad layer on a side of the second electrode layer away from the electroactive layer, the second pad layer being connected to the second electrode layer. Optionally, in a region where the orthographic projection of the second electrode layer on a base substrate overlaps with the orthographic projection of the second pad layer on the base substrate, at least 30% of the second pad layer is in direct contact with the second electrode layer.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A haptic substrate, comprising:
a first electrode layer;
an electroactive layer on the first electrode layer;
a second electrode layer on a side of the electroactive layer away from the first electrode layer;
a first pad layer electrically connected to the first electrode layer; and
a second pad layer on a side of the second electrode layer away from the electroactive layer, the second pad layer being connected to the second electrode layer;
wherein in a region where an orthographic projection of the second electrode layer on a base substrate overlaps with the orthographic projection of the second pad layer on the base substrate, at least 30% of the second pad layer is in direct contact with the second electrode layer.

2. The haptic substrate of claim 1, wherein in the region where the orthographic projection of the second electrode layer on the base substrate overlaps with the orthographic projection of the second pad layer on the base substrate, an entirety of the second pad layer is in direct contact with the second electrode layer.

3. The haptic substrate of claim 1, wherein at least 30% of the region where the orthographic projection of the second electrode layer on the base substrate overlaps with the orthographic projection of the second pad layer on the base substrate is absent of an insulating layer between the second electrode layer and the second pad layer.

4. The haptic substrate of claim 1, wherein an entirety of the region where the orthographic projection of the second electrode layer on the base substrate overlaps with the orthographic projection of the second pad layer on the base substrate is absent of an insulating layer between the second electrode layer and the second pad layer.

5. The haptic substrate of claim 1, comprising one or more units arranged along a first direction configured to perform tactile reproduction upon actuation;
wherein the electroactive layer comprises a plurality of electroactive blocks;
the second electrode layer comprises a plurality of second electrode blocks;
the second pad layer comprises a plurality of second pads; and
a respective unit of the one or more units comprises a respective electroactive block of the plurality of electroactive blocks, the plurality of second electrode blocks, and a respective second pad of the plurality of second pads.

6. The haptic substrate of claim 5, wherein the plurality of second electrode blocks in the respective unit are configured to form a first electric field with the first electrode layer;
the plurality of second pads in the respective unit are configured to transmit a signal to the second electrode layer to form a second electric field with the first electrode layer; and
the first electric field and the second electric field are in phase with respect to each other.

7. The haptic substrate of claim 5, wherein the respective second pad comprises a plurality of ring structures and a plurality of bridges alternately arranged along a second direction.

8. The haptic substrate of claim 7, wherein the respective unit comprises a plurality of subunits arranged along the second direction; and
a respective subunit comprises a respective second electrode block of the plurality of second electrode blocks, and a respective ring structure of the plurality of ring structures, adjacent ring structures of the plurality of ring structures being connected to each other through a respective bridge of the plurality of bridges.

9. The haptic substrate of claim 8, wherein an orthographic projection of the respective second electrode block on the base substrate completely covers an orthographic projection of an inner periphery of the respective ring structure on the base substrate; and
an orthographic projection of an outer periphery of the respective ring structure on the base substrate is at least partially overlapping with the orthographic projection of the respective second electrode block on the base substrate.

10. The haptic substrate of claim 8, wherein an entirety of the respective ring structure is in direct contact with the respective second electrode block.

11. The haptic substrate of claim 5, wherein the respective electroactive block is a unitary structure, the respective second pad is a unitary structure, and the plurality of second electrode blocks are spaced apart from each other.

12. The haptic substrate of claim 5, wherein an orthographic projection of the respective second pad on the base substrate at least partially overlaps with an orthographic projection of each of the plurality of second electrode blocks on the base substrate; and
the orthographic projection of the plurality of second electrode blocks on the base substrate covers at least 50% of the orthographic projection of the respective second pad on the base substrate.

13. The haptic substrate of claim 5, wherein an orthographic projection of the respective electroactive block on the base substrate covers at least 50% of an orthographic projection of the plurality of second electrode blocks on the base substrate; and
the orthographic projection of the respective electroactive block on the base substrate covers at least 50% of an orthographic projection of the respective second pad on the base substrate.

14. The haptic substrate of claim 5, wherein an orthographic projection of the respective electroactive block on the base substrate completely covers an orthographic projection of the plurality of second electrode blocks on the base substrate, and completely covers an orthographic projection of the respective second pad on the base substrate.

15. The haptic substrate of claim 5, wherein the respective second pad is in direct contact with each of the plurality of second electrode blocks; and
the respective electroactive block is in direct contact with each of the plurality of second electrode blocks.

16. The haptic substrate of claim 5, wherein the electroactive layer is a unitary electroactive layer spans over the one or more units.

17. The haptic substrate of claim 5, wherein the haptic substrate comprises two units configured to perform tactile reproduction upon actuation, the two units being on two sides of the haptic substrate, respectively.

18. The haptic substrate of claim 1, further comprising a planarization layer between the electroactive layer and the second electrode layer.

19. The haptic substrate of claim 1, wherein the haptic substrate is absent of any via through which the second pad layer is connected to the second electrode layer.

20. An electronic apparatus, comprising the haptic substrate of claim 1, and a driving circuit connected to the haptic substrate.
